(19) United States
(12) Patent Application Publication
(10) Pub. No.: US 2023/0296712 A1
(43) Pub. Date: Sep. 21, 2023

(54) METHOD FOR MONITORING PROBE CONDITION, TEST SYSTEM, COMPUTER DEVICE, AND STORAGE MEDIUM

(71) Applicant: CHANGXIN MEMORY TECHNOLOGIES, INC., Hefei City (CN)

(72) Inventors: Yongjun XING, Hefei City (CN); Xinyu HUANG, Hefei City (CN)

(21) Appl. No.: 17/805,909

(22) Filed: Jun. 8, 2022

Related U.S. Application Data
(63) Continuation of application No. PCT/CN2022/085175, filed on Apr. 2, 2022.

(30) Foreign Application Priority Data
Mar. 18, 2022 (CN) 202210270630.5

(51) Int. Cl. G01R 35/00

(52) U.S. Cl. CPC G01R 35/00; G01R 31/2831

(57) ABSTRACT

The present disclosure relates to a method for monitoring a probe condition, a test system, a computer device, and a storage medium. The method for monitoring a probe condition includes: acquiring test data of a sensitive test parameter which is obtained by a probe under a preset needle depth, wherein the sensitive test parameter is a test parameter sensitive to a contact resistance between the probe and a structure under test; and monitoring a condition of the probe according to the test data of the sensitive test parameter.

### CROSS-REFERENCE TO RELATED APPLICATIONS

This is a continuation of International Application No. PCT/CN2022/085175, filed on Apr. 02, 2022, which claims priority to Chinese Patent Application No. 202210270630.5, filed on Mar. 18, 2022 and entitled “METHOD FOR MONITORING PROBE CONDITION, TEST SYSTEM, COMPUTER DEVICE, AND STORAGE MEDIUM”. The entire contents of International Application No. PCT/CN2022/085175 and Chinese Patent Application No. 202210270630.5 are incorporated herein by reference.

### TECHNICAL FIELD

The present disclosure relates to the technical field of semiconductor testing, and in particular, to a method for monitoring a probe condition, a test system, a computer device, and a storage medium.

### BACKGROUND

In a manufacturing process of a semiconductor chip, it is generally necessary to test the chip to monitor the quality of the chip. As an electrical connector between a tester and a wafer, a probe plays an important role in the testing process.

During the testing process, the probe is in contact with a structure under test, and may pick up substances on the structure under test during the contact. As the test continues, the substances will accumulate on the probe, which increases the contact resistance between the probe and the structure under test, affecting the accuracy of test data.

In the current test procedure, the probe is generally cleaned after the test is completed. In such a method, it is difficult to detect the poor condition of the probe in time.

### SUMMARY

According to various embodiments of the present disclosure, a method and an apparatus for monitoring probe condition, a computer device, and a storage medium are provided.

According to various embodiments of the present disclosure, a method for monitoring a probe condition is provided, including:
acquiring test data of a sensitive test parameter which is obtained by a probe under a preset needle depth, wherein the sensitive test parameter is a test parameter sensitive to a contact resistance between the probe and a structure under test; and
monitoring a condition of the probe according to the test data of the sensitive test parameter.

According to some embodiments, the present disclosure further includes a test system, including:
a prober, including a probe card, wherein a plurality of probes are provided on the probe card;
a tester, electrically connected to the probe card to test a structure under test by using the probe on the probe card; and
a monitoring apparatus, electrically connected to the tester to acquire test data of a sensitive test parameter which is obtained by testing the structure under test by the plurality of probes under a preset needle depth, and monitor a condition of each of the probes according to the test data of the sensitive test parameter, wherein the sensitive test parameter is a test parameter sensitive to a contact resistance between the probe and the structure under test.

According to some embodiments, the present disclosure further provides a computer device, including a memory cell and a processing unit, wherein the memory cell stores a computer program, and the processing unit executes the computer program to implement the steps of the method described above.

According to some embodiments, the present disclosure further provides a computer-readable storage medium, which stores a computer program, wherein the computer program is executed to a processing unit to implement the steps of the method described above.

Details of one or more embodiments of the present disclosure will be illustrated in the following drawings and description. Other features, objectives, and advantages of the present disclosure become evident in the specification, claims, and accompanying drawings.

### BRIEF DESCRIPTION OF THE DRAWINGS

To describe the technical solutions in the embodiments of the present disclosure or in the prior art more clearly, the following briefly describes the drawings required for describing the embodiments or the prior art. Apparently, the drawings in the following description merely show some embodiments of the present disclosure, and a person of ordinary skill in the art may still derive other drawings from these drawings without creative efforts.

FIG. 1 is a schematic flowchart of a method for monitoring a probe condition according to an embodiment;

FIG. 2 is a schematic flowchart of a method for monitoring a probe condition according to another embodiment;

FIG. 3 is a schematic flowchart of determining the sensitive test parameter in a plurality of different test parameters according to an embodiment;

FIG. 4 shows test data graphs of various test parameters under different needle depths according to an embodiment;

FIG. 5 shows a test data graph of a sensitive test parameter of structures under test on a same batch of wafers according to an embodiment;

FIG. 6 is a structural block diagram of a test system according to an embodiment;

FIG. 7 is a structural block diagram of a test system according to another embodiment; and

FIG. 8 is a diagram of an internal structure of a computer device according to an embodiment.

To better describe and illustrate the embodiments and/or examples of the present disclosure, reference may be made to one or more accompanying drawings. Additional details or examples for describing the drawings should not be considered as limitations on the scope of any one of the present disclosure, the currently described embodiment and/or example, and the optimal mode of the present disclosure as currently understood.

### DETAILED DESCRIPTION

To facilitate the understanding of the present disclosure, the present disclosure is described more completely below with reference to the related accompanying drawings. The preferred embodiments of the present disclosure are shown in the accompanying drawings. However, the present disclosure may be embodied in various forms without being limited to the embodiments described herein. On the contrary, these embodiments are provided to make the present disclosure more thorough and comprehensive.

The terms used in the specification of the present disclosure are merely for the purpose of describing specific embodiments, rather than to limit the present disclosure.

It should be noted that when a component is “connected” to another component, the component may be connected to the another component directly or via an intermediate component. In addition, a “connection” in the following embodiments should be understood as an “electrical connection” or a “communication connection” if connected objects have electrical signal or data transmission between each other.

In the specification, the singular forms of “a”, “an” and “the/this” may also include plural forms, unless clearly indicated otherwise. It should also be understood that the terms such as “including/comprising” and “having” indicate the existence of the stated features, wholes, steps, operations, components, parts or combinations thereof. However, these terms do not exclude the possibility of the existence of one or more other features, wholes, steps, operations, components, parts or combinations thereof.

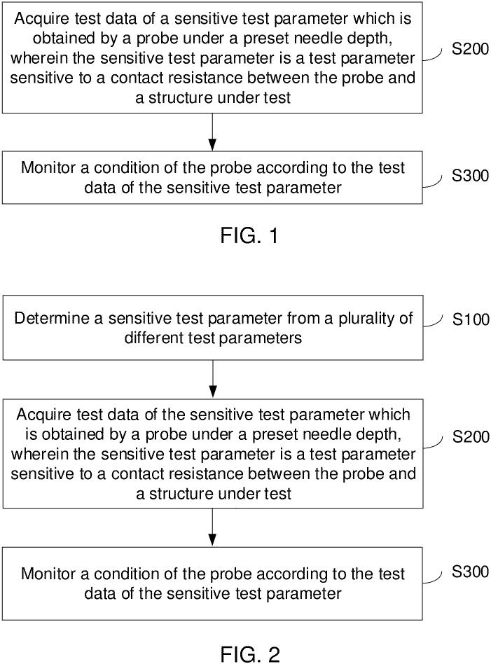

In an embodiment, referring to FIG. 1, a method for monitoring a probe condition is provided, including the following steps:

Step S200: Acquire test data of a sensitive test parameter which is obtained by a probe under a preset needle depth, wherein the sensitive test parameter is a test parameter sensitive to a contact resistance between the probe and a structure under test.

Step S300: Monitor a condition of the probe according to the test data of the sensitive test parameter.

In step S200, the probe is used for testing a structure under test of a wafer (such as a wafer acceptance test).

Specifically, a plurality of structures under test may be provided on a same wafer. The structure under test includes a body structure under test and a pad.

Meanwhile, a tester and a prober are main devices for wafer testing. A probe card for electrically connecting the tester and the wafer is installed on the prober. Specifically, a plurality of probes are provided on the probe card. The probes are in contact with the pad of the structure under test of the wafer, so as to test the structure under test.

For example, test data of the sensitive test parameter which is obtained by a plurality of probes under a preset needle depth may be acquired. The term “plurality of probes” may be a plurality of probes on a same probe card, or a plurality of probes on a plurality of probe cards, which is not limited therein.

Moreover, for example, “the plurality of probes” are used for testing the structure under test on a same wafer or a same batch of wafers. The same process is adopted for the same wafer or the same batch of wafers. Therefore, the monitoring result of the probe condition is not affected by process factors.

Specifically, the plurality of probes testing, under the preset needle depth, the structure under test may mean that the plurality of probes test a plurality of different structures under test. Each probe may test one structure under test, or each probe may test a plurality of (more than one) structures under test at different moments.

The contact resistance between the probe and the structure under test is affected by the surface clearness of the probe, the needle depth, and the like. For the probe with the same surface clearness, different needle depths of the probe on the structure under test (specifically the pad of the structure under test) result in different contact resistances between the probe and the structure under test. Under the circumstance wherein the structure under test is not destroyed, a larger needle depth corresponds to better contact between the probe and the structure under test and a smaller contact resistance. On the contrary, a smaller needle depth corresponds to a poorer contact between the probe and the structure under test and a larger contact resistance.

In this embodiment, the test data of the sensitive test parameter which is obtained by the probe under the preset needle depth is acquired. Therefore, the surface clearness of the probe, i.e., the probe condition, can be determined according to the test data.

In step S300, under the preset needle depth, the test data of the sensitive test parameter has a corresponding preset range. The range is related to the needle depth, and may be acquired based on related history data or experimental data.

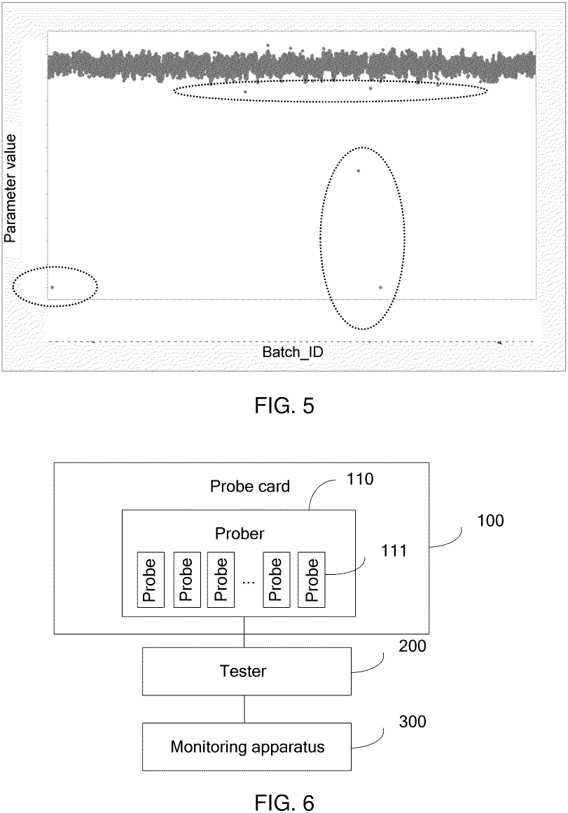

When a plurality of pieces of test data of the sensitive test parameter which are obtained by a plurality of probes are acquired, it may be determined whether there is any abnormal test data exceeding the preset range (for example, data in the dotted frames in FIG. 5). Then, a probe corresponding to the abnormal test data is acquired, thereby monitoring the condition of each probe.

In this embodiment, the contact resistance between the probe and the structure under test affects the test data of the sensitive test parameter. When testing is performed under a fixed preset needle depth, the needle depth has a fixed effect on the contact resistance between the probe and the structure under test. Therefore, the contact resistance between the probe and the structure under test changes with the probe condition. When the condition of a probe is abnormal, the contact resistance between the probe and the structure under test becomes abnormal, causing the test data of the sensitive test parameter to be abnormal. Therefore, in this embodiment, the test data of the sensitive test parameter which is obtained by the probe under the preset needle depth is acquired, so that the condition of the probe can be effectively monitored.

In an embodiment, referring to FIG. 2, before step S200, the method further includes the following step:

Step S100: Determine the sensitive test parameter from a plurality of different test parameters.

During testing for the structure under test of the wafer, a plurality of test parameters are tested generally. The contact resistance between the probe and the structure under test has different degrees of impact on different test parameters during measurement. Therefore, a suitable test parameter is first selected from the test parameters to serve as the sensitive test parameter, which can effectively improve the accuracy of probe condition monitoring.

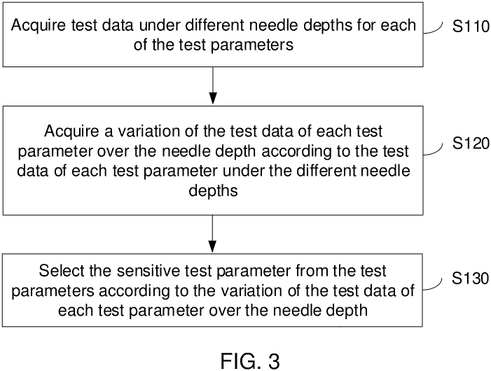

In an embodiment, referring to FIG. 3, step S100 includes the following steps:

Step S110: Acquire test data under different needle depths for each of the test parameters.

Step S120: Acquire variations of the test data of each test parameter over the needle depths according to the test data of each test parameter under the different needle depths.

Step S130: Select the sensitive test parameter from the test parameters according to the variations of the test data of each test parameter over the needle depths.

In step S110, different needle depths include a plurality of needle depths.

For example, for each test parameter, test data under the same set of needle depths can be acquired. In this case, related data of the test parameters can be more objective and effective.

Specifically, for example, when the structure under test on the wafer is tested, three test parameters: parameter A, parameter B, and parameter C, are tested. For parameter A, test data of the structure under test under the needle depths of OD1, OD2, OD3, OD4, OD5, and OD6 is acquired. For parameter B, test data of the structure under test under the needle depths of OD1, OD2, OD3, OD4, OD5, and OD6 is acquired. For parameter C, test data of the structure under test under the needle depths of OD1, OD2, OD3, OD4, OD5, and OD6 is acquired.

Meanwhile, for example, multiple sets of test data are acquired for the same test parameter. Each set of data may correspond to one structure under test. Different sets of data may be test data corresponding to different structures under test. In this case, a more accurate result can be obtained based on multiple sets of data.

Specifically, for parameter A, 12 sets of test data may be acquired. Each set of data includes test data under the needle depths of OD1, OD2, OD3, OD4, OD5 and OD6. For parameter B, 12 sets of test data may be acquired. Each set of data includes test data under the needle depths of OD1, OD2, OD3, OD4, OD5 and OD6. For parameter C, 12 sets of test data may be acquired. Each set of data includes test data under the needle depths of OD1, OD2, OD3, OD4, OD5 and OD6.

In Step S120, a corresponding relational graph may be drawn according to the test data of each test parameter under the different needle depths.

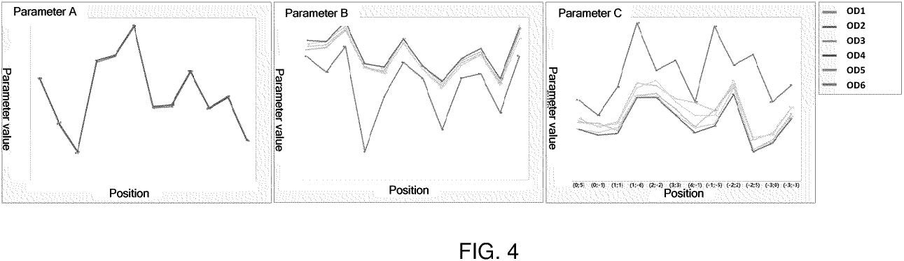

Specifically, referring to FIG. 4, when the test data under the same set of needle depths is acquired for the test parameters and multiple sets of test data are acquired for each test parameter, for the same test parameter, parameter values under the same needle depth that are taken from the multiple sets of test data may be connected into a line, thereby forming a plurality of data lines under different needle depths. In this case, variations of the test data of each test parameter over the needle depths are reflected by the relationship among the data lines of each test parameter.

For example, for parameter A, parameter values under the needle depths of OD1, OD2, OD3, OD4, OD5, and OD6 in the sets of test data may be connected respectively, to form six data lines corresponding to the needle depths of OD1, OD2, OD3, OD4, OD5, and OD6. For parameter B, parameter values under the needle depths of OD1, OD2, OD3, OD4, OD5, and OD6 in the sets of test data may be connected respectively, to form six data lines corresponding to the needle depths of OD1, OD2, OD3, OD4, OD5, and OD6. For parameter C, parameter values under the needle depths of OD1, OD2, OD3, OD4, OD5, and OD6 in the sets of test data may be connected respectively, to form six data lines corresponding to the needle depths of OD1, OD2, OD3, OD4, OD5, and OD6.

In step S130, the sensitive test parameter may be selected from the test parameters according to the relationship among the data lines of each test parameter.

Specifically, referring to FIG. 4, it can be learned that the test data of parameter A, the test data of parameter B, and the test data of parameter C change differently as the needle depth OD changes. The test data of parameter A is relatively stable as the needle depth OD changes, and the test data of parameter C changes significantly as the needle depth OD changes.

Certainly, the specific embodiments above are exemplary implementations, which are not limited herein. For example, for different test parameters, test data under different sets of needle depths may be obtained. For one test parameter, only one set of test data may be obtained. Certainly, when only one set of test data is acquired for one test parameter, in step S120, a relational graph between test parameter values and needle depths for each test parameter may also be drawn.

In this embodiment, different contact resistances are simulated by adjusting the needle depth, to test the sensitivity of different test parameters to the contact resistance, thereby determining the sensitive test parameter accurately and effectively.

Certainly, in other embodiments, the sensitive test parameter may be determined from the test parameters in other manners. For example, a probe with a clean surface and a probe with foreign matter (such as aluminum scraps) on the surface are used for measuring test parameters of a same structure under test, and then the degrees of impact of the probe surface clearness on the test parameters are compared, to determine the sensitive test parameter.

Alternatively, in some embodiments, the sensitive test parameter may be directly determined by related operators based on their working experience, which is not limited in the present disclosure.

In an embodiment, the step of acquiring test data under different needle depths for each of the test parameters includes the following steps:

Step S1: Select a plurality of structures under test and a plurality of test probes corresponding to the structures under test.

Step S2: Set a plurality of needle depths, and acquire, under the needle depths, test data of each test parameter of each structure under test.

In step S1, specifically, the plurality of structures under test may be located on a same wafer. The plurality of test probes corresponding to the structures under test may be located on a same probe card.

For example, step S2 may include the following steps:

Step S21: Set an initial needle depth, and acquire test data of each test parameter under the initial needle depth.

Step S22: Gradually increase the needle depth to a critical needle depth, and acquire test data of each test parameter under each corresponding needle depth.

Specifically, during testing, when the structure under test is tested under one needle depth, all the test parameters are tested, so that test data of all the test parameters can be acquired in one test.

When one structure under test is tested under different needle depths, test data under one set of different needle depths is acquired for each test parameter. When a plurality of structures under test are simultaneously tested under different needle depths, multiple sets of test data under different needle depths may be obtained for each test parameter.

Meanwhile, a larger needle depth corresponds to better contact and a smaller contact resistance between the probe and the structure under test. However, if exceeding the upper limit, the needle depth may damage the structure under test. Therefore, by gradually increasing the needle depth, the structure under test can be prevented from being damaged.

For example, the initial needle depth may be 1 µm to 5 µm, the critical needle depth may be 95 µm to 100 µm. In step S22, the needle depth may be increased by 5 µm each time.

Certainly, in other examples, the needle depth may not be increased gradually, which is not limited herein.

In this embodiment, in the process of monitoring the probe condition (specifically, determining the sensitive test parameter), experimental test data of previous experiment may be retrieved directly, without the need to acquire related test data through experiment in the monitoring process. Certainly, the present disclosure is not limited thereto. In some cases, in the process of monitoring the probe condition (specifically, determining the sensitive test parameter), experiment may be performed in real time according to actual requirements.

In an embodiment, step S300 includes the following steps:

Step S410: Acquire probe condition corresponding to abnormal test data according to the test data of the sensitive test parameter.

Step S420: Determine that a probe is abnormal if abnormal test data corresponding to the probe is greater than a preset amount, wherein the preset amount is a positive integer greater than 1.

In step S410, it may be determined whether there is abnormal test data according to multiple pieces of test data of the sensitive test parameter acquired by testing a plurality of structures under test on the same wafer or the same batch of wafers.

Meanwhile, when the plurality of structures under test on the same wafer or the same batch of wafers are tested, the same probe may be used for testing different structures under test at different moments. Therefore, one probe may correspond to multiple pieces of different test data.

When abnormal test data exists, the probe corresponding to the abnormal test data may be acquired. Then, the amount of abnormal test data corresponding to each probe that is obtained according to the abnormal test data is acquired, thereby obtaining the probe condition corresponding to the abnormal test data.

In step S420, the preset amount may be set according to actual requirements.

In actual testing, in addition to the probe exception, other factors (such as software exception) may also cause the test data of the test parameter to be abnormal. Therefore, if the abnormal test data occurs, it is determined that the probe corresponding to the abnormal test data is abnormal, which may lead to misjudgment.

When the amount of abnormal test data corresponding to one probe is greater than the preset amount, it indicates that these pieces of abnormal test data corresponding to the probe are not independent occasional pieces of abnormal data. These pieces of abnormal test data are regularly related to the probe, and the probe can be determined as abnormal on this basis.

Based on this, when the amount of abnormal test data corresponding to one probe is not greater than the preset amount, it may be temporarily determined that the probe is normal, or whether the probe is normal or not needs to be further determined.

In this embodiment, a probe is determined as abnormal only when the amount of abnormal test data corresponding to the probe is greater than the preset amount, thereby effectively preventing misjudgment.

In an embodiment, after step S420, the method may further include the following step:

Step S430: Control to clean the abnormal probe.

Specifically, after each abnormal probe is determined, a related cleaning apparatus may be controlled to automatically clean the probes, thereby effectively cleaning the abnormal probes in real time.

Certainly, in other embodiments, after each abnormal probe is determined, the corresponding probes may be cleaned manually, which is not limited herein.

In an embodiment, after step S200, the method further includes: displaying the test data of the sensitive test parameter.

To display the test data of the sensitive test parameter means to display the test data of the sensitive test parameter which is obtained by testing the structure under test by the plurality of probes under the preset needle depth. For example, the test data of the sensitive test parameter of a plurality of structures under test on the same wafer or the same batch of wafers may be displayed.

Specifically, referring to FIG. 5, a drawing may be made according to the test data of the sensitive test parameter of the plurality of structures under test on the same batch of wafers, and then displayed.

The test data of the sensitive test parameter acquired in step S200 is displayed, so that the related operator can preliminarily determine the overall condition of all the probes for testing.

It should be understood that although the steps in the flowcharts of FIG. 1 to FIG. 3 are shown in turn as indicated by arrows, these steps are not necessarily performed in turn as indicated by the arrows. The execution order of the steps is not strictly limited, and the steps may be executed in other orders, unless clearly described otherwise. Moreover, at least some of the steps in FIG. 1 to FIG. 3 may include a plurality of sub-steps or stages. The sub-steps or stages are not necessarily executed at the same time, but may be executed at different times. The sub-steps or stages are not necessarily carried out sequentially, but may be executed alternately with other steps or at least some of sub-steps or stages of other steps.

In an embodiment, referring to FIG. 6, a test system is further provided, including a prober 100, a tester 200, and a monitoring apparatus 300.

The prober 100 includes a probe card 110. A plurality of probes 111 are provided on the probe card. The tester 200 is electrically connected to the probe card 110, so as to test a structure under test by using the probes 111 on the probe card 110.

The monitoring apparatus 300 is electrically connected to the tester 200, to acquire test data of a sensitive test parameter which is obtained by testing the structure under test by the plurality of probes under a preset needle depth, and monitor condition of each probe according to the test data of the sensitive test parameter. The sensitive test parameter is a test parameter sensitive to a contact resistance between the probe and the structure under test.

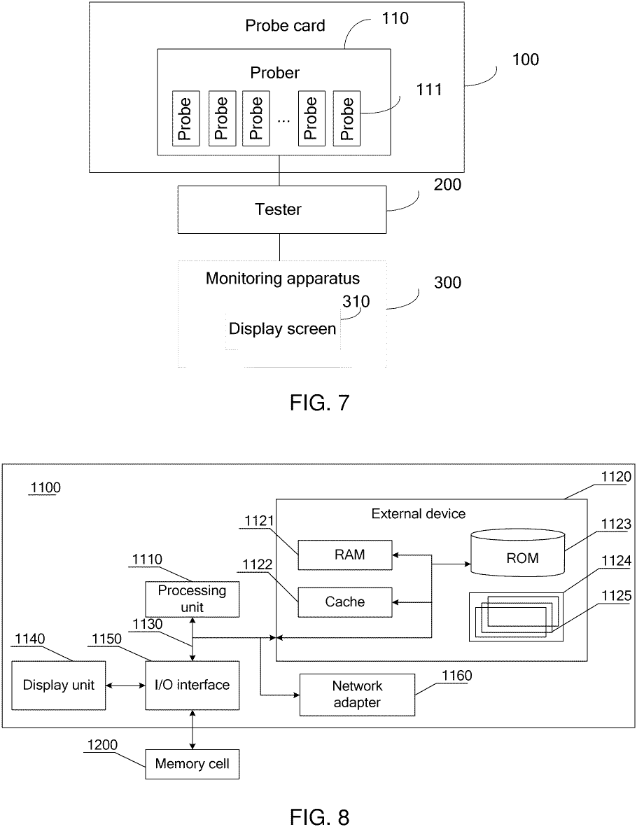

In an embodiment, referring to FIG. 7, the monitoring apparatus 300 includes a display screen 310. The display screen 310 is configured to display the test data of the sensitive test parameter.

In addition, the monitoring apparatus 300 may be an apparatus independent of the tester 200.

Certainly, in some embodiments, the monitoring apparatus 300 may be integrated in the tester 200, which is not limited herein. In this case, the test data of the sensitive test parameter may be displayed on the display screen of the tester 200.

For the specific limitation on the test system, reference may be made to the limitation on the foregoing method for monitoring a probe condition. Details are not described herein again. The monitoring apparatus of the test system may be partially or completely implemented by software, hardware, or a combination thereof. The modules may be embedded in or independent of a processing unit of a computer device in a form of hardware, or stored in a memory of the computer device in a form of software, such that the processor can easily invoke and execute corresponding operations of the modules. It should be noted that the division of modules in the embodiment of the present disclosure is schematic, which is only logical function division, and there may be another division method in actual implementation.

In an embodiment, referring to FIG. 8, a computer device 1100 is provided. Components of the computer device 1100 may include, but are not limited to, at least one processing unit 1110, at least one memory cell 1120, a bus 1130 connecting different system components (including the processing unit 1110 and the memory cell 1120), and a display unit 1140.

The memory cell 1120 stores a computer program, and the processing unit 1110 executes the computer program to implement the following steps:

acquiring test data of a sensitive test parameter which is obtained by testing a structure under test by a plurality of probes under a preset needle depth, wherein the sensitive test parameter is a test parameter sensitive to a contact resistance between the probe and the structure under test; and monitoring a condition of each probe according to the test data of the sensitive test parameter.

In an embodiment, the processing unit executes the computer program to further implement the following step:

determining the sensitive test parameter from a plurality of different test parameters.

In an embodiment, the processing unit executes the computer program to further implement the following steps:

acquiring test data of each of the plurality of different test parameters under different needle depths; acquiring variations of the test data of each test parameter over the needle depths according to the test data of each test parameter under the different needle depths; and selecting the sensitive test parameter from the test parameters according to the variations of the test data of each test parameter over the needle depths.

In an embodiment, the processing unit executes the computer program to further implement the following step:

acquiring test data of each test parameter obtained by testing a plurality of structures under test under different needle depths, wherein all the test parameters are tested when one structure under test is tested under one needle depth.

In an embodiment, the processing unit executes the computer program to further implement the following step:

selecting the preset needle depth from the plurality of needle depths.

In an embodiment, the processing unit executes the computer program to further implement the following step:

acquiring test data of the sensitive test parameter which is obtained by testing a plurality of structures under test on a same wafer or a same batch of wafers by a plurality of probes under the preset needle depth.

In an embodiment, the processing unit executes the computer program to further implement the following steps:

acquiring probe condition corresponding to abnormal test data according to the test data of the sensitive test parameter; and determining that a probe is abnormal if abnormal test data corresponding to the probe is greater than a preset amount, wherein the preset amount is a positive integer greater than 1.

In an embodiment, the processing unit executes the computer program to further implement the following step:

controlling to clean the abnormal probe.

In an embodiment, the processing unit executes the computer program to further implement the following step:

displaying the test data of the sensitive test parameter.

The memory cell 1120 may include a readable medium in the form of a volatile memory cell, for example, a random access memory (RAM) cell 1121 and/or a cache memory cell 1122, and may further include a read-only memory (ROM) cell 1123.

The memory cell 1120 may alternatively include a program/utility 1124 including a set of (at least one) program modules 1125, and the program module includes, but is not limited to: an operating system, one or more applications, other program modules and program data. Each of these examples or some combination thereof may include an implementation of a network environment.

The bus 1130 may be one or more of several types of bus structures, including a memory cell bus or a memory cell controller, a peripheral bus, a graphics acceleration port, a processing unit, or a local area bus using any of various bus structures.

The computer device 1100 may further communicate with one or more external devices 1200 (for example, a keyboard, a pointing device, or a Bluetooth device, or a display device), with one or more devices that enable a user to interact with the computer device 1100, and/or with any device that enables the computer device 1100 to communicate with one or more other computing devices (for example, a router or a modem). Such communication may be performed through an input/output (I/O) interface 1150. The computer device 1100 may further communicate with one or more networks (for example, a local area network (LAN), a wide area network (WAN), and/or a public network such as the Internet) through a network adapter 1160. As shown in FIG. 8, the network adapter 1160 communicates with other modules of the computer device 1100 through the bus 1130. It should be understood that although not shown in the figure, other hardware and/or software modules may be used in combination with the computer device 1100, including but not limited to: microcode, a device driver, a redundant processing unit, an external disk drive array, an RAID system, a tape driver, and a data backup storage system.

In an embodiment, a computer-readable storage medium is provided. The computer-readable storage medium stores a computer program, and the computer program is executed by a processing unit to implement the following steps:

acquiring test data of a sensitive test parameter which is obtained by testing a structure under test by a plurality of probes under a preset needle depth, wherein the sensitive test parameter is a test parameter sensitive to a contact resistance between the probe and the structure under test; and monitoring condition of each probe according to the test data of the sensitive test parameter.

In an embodiment, the computer program is executed by the processing unit to further implement the following step: determining the sensitive test parameter from a plurality of different test parameters.

In an embodiment, the computer program is executed by the processing unit to further implement the following steps:

acquiring test data of each of the plurality of different test parameters under different needle depths; acquiring variations of the test data of each test parameter over the needle depths according to the test data of each test parameter under the different needle depths; and selecting the sensitive test parameter from the test parameters according to the variations of the test data of each test parameter over the needle depths.

In an embodiment, the computer program is executed by the processing unit to further implement the following step:

acquiring test data of each test parameter obtained by testing a plurality of structures under test under different needle depths, wherein all the test parameters are tested when one structure under test is tested under one needle depth.

In an embodiment, the computer program is executed by the processing unit to further implement the following step:

selecting the preset needle depth from the plurality of needle depths.

In an embodiment, the computer program is executed by the processing unit to further implement the following step:

acquiring test data of the sensitive test parameter which is obtained by testing a plurality of structures under test on a same wafer or a same batch of wafers by a plurality of probes under the preset needle depth.

In an embodiment, the computer program is executed by the processing unit to further implement the following steps:

acquiring probe condition corresponding to abnormal test data according to the test data of the sensitive test parameter; and determining that a probe is abnormal if abnormal test data corresponding to the probe is greater than a preset amount, wherein the preset amount is a positive integer greater than 1.

In an embodiment, the computer program is executed by the processing unit to further implement the following step:

controlling to clean the abnormal probe.

In an embodiment, the computer program is executed by the processing unit to further implement the following step:

displaying the test data of the sensitive test parameter.

Those of ordinary skill in the art may understand that all or some of the procedures in the methods of the above embodiments may be implemented by a computer program instructing related hardware. The computer program may be stored in a non-volatile computer-readable storage medium. When the computer program is executed, the procedures in the embodiments of the above methods may be performed. Any reference to a memory, a storage, a database, or other media used in the embodiments of the present disclosure may include at least one of a non-volatile memory and a volatile memory. The non-volatile memory may include a read-only memory (ROM), a magnetic tape, a floppy disk, a flash memory, or an optical memory. The volatile memory may include a random access memory (RAM) or an external cache memory. As an illustration rather than a limitation, the RAM may be in various forms, such as a static random access memory (SRAM) or a dynamic random access memory (DRAM).

In the specification, the description of terms such as “one of the embodiments”, “some embodiments”, “other embodiments” means that a specific feature, structure, material or characteristic described in combination with the embodiment(s) or example(s) are included in at least one embodiment or example of the present disclosure. In the specification, the schematic description of the above terms does not necessarily refer to the same embodiment or example.

The technical characteristics of the above embodiments can be employed in arbitrary combinations. To provide a concise description of these embodiments, all possible combinations of all the technical characteristics of the above embodiments may not be described; however, these combinations of the technical characteristics should be construed as falling within the scope defined by the specification as long as no contradiction occurs.

The above embodiments are only intended to illustrate several implementations of the present disclosure in detail, and they should not be construed as a limitation to the patentable scope of the present disclosure. It should be noted that those of ordinary skill in the art can further make variations and improvements without departing from the conception of the present disclosure. These variations and improvements all fall within the protection scope of the present disclosure. Therefore, the protection scope of the present disclosure should be subject to the protection scope defined by the claims.

1. A method for monitoring a probe condition, comprising:
acquiring test data of a sensitive test parameter which is obtained by a probe under a preset needle depth, wherein the sensitive test parameter is a test parameter sensitive to a contact resistance between the probe and a structure under test; and
monitoring a condition of the probe according to the test data of the sensitive test parameter.

2. The method for monitoring the probe condition according to claim 1, wherein before the acquiring test data of a sensitive test parameter which is obtained by a probe under a preset needle depth, the method further comprises:
determining the sensitive test parameter from a plurality of different test parameters.

3. The method for monitoring the probe condition according to claim 2, wherein the determining the sensitive test parameter from a plurality of different test parameters comprises:
acquiring test data under different needle depths for each of the test parameters;
acquiring a variation of the test data of each test parameter over the needle depth according to the test data of each test parameter under the different needle depths; and
selecting the sensitive test parameter from the test parameters according to the variation of the test data of each test parameter over the needle depth.

4. The method for monitoring the probe condition according to claim 3, wherein the step of acquiring test data under different needle depths for each of the test parameters comprises:
selecting a plurality of structures under test and a plurality of test probes corresponding to the structures under test; and
setting a plurality of needle depths, and acquiring, under each needle depth, test data of each test parameter of each structure under test.

5. The method for monitoring the probe condition according to claim 4, wherein the setting a plurality of needle depths, and acquiring, under each needle depth, test data of each test parameter of each structure under test comprises:
setting an initial needle depth, and acquiring test data of each test parameter under the initial needle depth; and
gradually increasing the needle depth to a critical needle depth, and acquiring test data of each test parameter under each corresponding needle depth.

6. The method for monitoring the probe condition according to claim 5, wherein the initial needle depth is 1 µm to 5 µm, and the critical needle depth is 95 µm to 100 µm.

7. The method for monitoring the probe condition according to claim 1, wherein the acquiring test data of a sensitive test parameter which is obtained by a probe under a preset needle depth comprises:
acquiring the test data of the sensitive test parameter obtained by a plurality of probes under the preset needle depth.

8. The method for monitoring the probe condition according to claim 7, wherein the plurality of probes are used for testing the structure under test on a same wafer or a same batch of wafers.

9. The method for monitoring the probe condition according to claim 1, wherein the monitoring a condition of the probe according to the test data of the sensitive test parameter comprises:
acquiring probe condition corresponding to abnormal test data according to the test data of the sensitive test parameter; and
determining that a probe is abnormal when abnormal test data corresponding to the probe is greater than a preset amount, wherein the preset amount is a positive integer greater than 1.

10. The method for monitoring the probe condition according to claim 9, wherein after the determining that a probe is abnormal when abnormal test data corresponding to the probe is greater than a preset amount, the method further comprises:
controlling to clean the abnormal probe.

11. The method for monitoring the probe condition according to claim 1, wherein after the acquiring test data of a sensitive test parameter which is obtained by testing a structure under test by a plurality of probes under a preset needle depth, the method further comprises:
displaying the test data of the sensitive test parameter.

12. A test system, comprising:
a prober, comprising a probe card, wherein a plurality of probes are provided on the probe card;
a tester, electrically connected to the probe card to test a structure under test by using the probe on the probe card; and
a monitoring apparatus, electrically connected to the tester to acquire test data of a sensitive test parameter which is obtained by testing the structure under test by the plurality of probes under a preset needle depth, and monitor a condition of each of the probes according to the test data of the sensitive test parameter, wherein the sensitive test parameter is a test parameter sensitive to a contact resistance between the probe and the structure under test.

13. The test system according to claim 12, wherein the monitoring apparatus comprises:
a display screen, configured to display the test data of the sensitive test parameter.

14. A computer device, comprising a memory cell and a processing unit, wherein the memory cell stores a computer program, and the computer program is executed by the processing unit to implement the steps of the method according to claim 1.

15. A computer-readable storage medium, storing a computer program, wherein the computer program is executed by a processing unit to implement the steps of the method according to claim 1.
